(19) United States
(12) Patent Application Publication
(10) Pub. No.: US 2025/0226637 A1
(43) Pub. Date: Jul. 10, 2025

(54) OPTOELECTRONIC DEVICE

(71) Applicant: ams-OSRAM International GmbH, Regensburg (DE)

(72) Inventors: Tansen VARGHESE, Regensburg (DE); Dirk BECKER, Langquaid (DE); Alvaro GOMEZ-IGLESIAS, Regensburg (DE)

(73) Assignee: ams-OSRAM International GmbH, Regensburg (DE)

(21) Appl. No.: 18/700,256

(22) PCT Filed: Sep. 8, 2022
(86) PCT No.: PCT/EP2022/074962

§ 371 Date: Apr. 10, 2024

(30) Foreign Application Priority Data
Oct. 15, 2021 (DE) 10 2021 126 769.2

(51) Int. Cl. H01S 5/026; H01S 5/02315

(52) U.S. Cl. CPC H01S 5/0262; H01S 5/02315; H01S 5/0261

(57) ABSTRACT

An optoelectronic device is specified including an emitter arranged to emit electromagnetic radiation and configured to be operated with an input voltage, a receiver arranged to receive the electromagnetic radiation and configured to provide at least part of an output voltage, wherein the emitter and the receiver are grown laterally adjacent to each other.

### CROSS-REFERENCE TO RELATED APPLICATIONS

The present application is a national stage entry from International Application No. PCT/EP2022/074962, filed on Sep. 8, 2022, published as International Publication No. WO 2023/061669 A1 on Apr. 20, 2023, and claims priority to German Patent Application No. 10 2021 126 769.2, filed Oct. 15, 2021, the disclosures of all of which are hereby incorporated by reference in their entireties.

### FIELD

An optoelectronic device is specified herein.

### BACKGROUND

A problem to be solved is to specify an optoelectronic device which can be designed to be particularly compact.

### SUMMARY

According to at least one aspect, the optoelectronic device comprises an emitter. The emitter is configured to emit electromagnetic radiation. For example, the emitter may be a device that generates electromagnetic radiation in the wavelength range between infrared radiation and ultraviolet radiation. In particular, the emitter may be configured to generate electromagnetic radiation in the wavelength range from at least 350 nm to at most 1600 nm during operation. Further, the emitter is adapted to be operated with an input voltage. For example, the optoelectronic device comprises two or more emitters which are connected in parallel with each other. The emitter or the emitters are configured to be operated with an input voltage.

According to at least one aspect of the optoelectronic device, the optoelectronic device comprises a receiver.

The receiver is configured to receive the electromagnetic radiation of an emitter and to provide part of an output voltage of the optoelectronic device. In particular, the receiver is configured to receive the electromagnetic radiation emitted by the emitter during operation and to convert it at least partially into electrical energy. In particular, the receiver can be tuned to the emitter in such a way that the receiver has a particularly high absorption for the electromagnetic radiation generated by the emitter.

According to at least one aspect of the optoelectronic device, the emitter and the receiver are grown laterally adjacent to each other. In particular, the emitter and the receiver are grown simultaneously. That is to say, in lateral directions both elements are arranged for example side by side. The lateral directions are e.g. parallel to an area of main extension of an active zone of the emitter and/or an active region of the receiver. In particular, the emitter and the receiver are semiconductor devices which are epitaxially grown along a growth direction onto a common growth substrate which acts as a carrier for the emitter and the receiver. The lateral directions are then e.g. perpendicular to the growth direction and the growth direction is parallel to a vertical direction.

The growth substrate can be present in the device or the growth substrate is removed and e.g. replaced by a different kind of carrier. For example, the emitter and the receiver are physically connected to each other via the carrier. For example, it is possible that the emitter and the receiver are in direct physical contact with each other and for example joined by a common layer or layer sequence.

According to at least one aspect of the optoelectronic device, the optoelectronic device comprises
an emitter configured to emit electromagnetic radiation and configured to be operated with an input voltage,
a receiver configured to receive the electromagnetic radiation and configured to provide at least part of an output voltage, wherein
the emitter and the receiver are grown laterally adjacent to each other.

According to at least one aspect of the optoelectronic device, the receiver comprises at least one photodiode. The photodiode may comprise a semiconductor body having at least one active or detecting region configured to absorb electromagnetic radiation generated by the emitter during operation and convert it into electrical energy. The photodiode may be formed, for example, in the same material system as the emitter. In particular, the receiver may comprise a plurality of photodiodes that may be connected together in series or in parallel.

The optoelectronic device described herein is based on the following considerations, among others.

Many applications, such as in acoustics, beam steering technologies such as MEMS, actuators, detectors such as avalanche photodiodes, single photon avalanche diodes, or photomultipliers, require high voltage supplies with relatively low power consumption. Such applications may require voltages in excess of 50 V, 100 V, 500 V, 1000 V, 2000 V, 10000 V, and more, while maintaining a small device footprint in terms of size, weight, cost, and power consumption. These characteristics are especially important for mobile devices such as AR/VR glasses, wearable in-ear headsets, and automotive applications.

Another problem to be solved for high-voltage generators with small footprint is the connection of low-voltage and high-voltage paths, which should be galvanically separated to ensure the functional reliability and long-term stability of a device under changing environmental conditions such as temperature, humidity, dust.

The optoelectronic device described here can advantageously be used as an optical voltage converter. Further, with the optoelectronic device described herein, it is also possible to convert a high voltage on the side of the emitters to a low voltage on the side of the receivers. Furthermore, with the present device, it is possible to transform an AC voltage into a DC voltage and vice versa. Finally, the present device also makes it possible to transfer galvanically isolated power from the side of the emitters to the side of the receivers without changing the voltage.

The optoelectronic device described here can thus form, for example, a transformer that can do without inductive elements, in particular without coils. On the one hand, this makes the installation space particularly small compared to conventional transformers, and on the other hand, no or only small magnetic fields are generated during the transformation. This also rules out any influence from external magnetic and/or electric fields. Thus, the optoelectronic device can be used in areas for which magnetic interference would be critical or which are subject to high external magnetic fields. At the same time, the optical power transmission in the optoelectronic device ensures galvanic isolation from the high-voltage side and the low-voltage side.

Another idea of the device described here is to combine semiconductor light emitters and receivers, i.e. photodiodes or photovoltaic cells, to achieve a conversion from low to high voltage. For this purpose on the low voltage side of the device, one or more emitters connected in parallel emit light. The wavelength of the emitted light can be between 350 nm and 1600 nm, depending on the semiconductor materials used, for example: In(Ga)N, In(Ga)AlP, (Al)GaAs, (In)GaAs. Typical input voltages are 1 V, 3 V, 5 V, 8 V, 10 V or in between.

On the high voltage side, which is galvanically isolated from the low voltage side, series-connected receivers, e.g. photodiodes operating in photovoltaic mode, collect the emitted light. Depending on the material used, for example Si, InGaAs, GaAs, InGaN or perovskite, the photodiode generates a voltage in the order of 0.5-3 V and a current depending on the intensity of the incident light. By using multijunction photodiodes, one can increase the output of a single photodiode stack. By using a large number of photodiodes, all of which can be connected in series on a very small wafer scale, these individual voltages add up to a high total voltage that can exceed 10, 50, 100, 500, 1000, or 10000 V.

Overall, the present device enables the transmission of energy and/or the conversion of voltage in a particularly compact component. The optoelectronic device is thereby insensitive to external influences such as temperature fluctuations or electromagnetic fields.

As a further advantage there are no optical alignment problems between the emitter side of the device and the receiver side of the device due to the fact that the emitter and the receiver are grown laterally adjacent to each other. Further, packaging of the device can be done with low effort as receiver and emitter can already be connected by a common carrier.

According to at least one aspect of the optoelectronic device, the emitter comprises an active zone which is configured to produce the electromagnetic radiation and the receiver comprises an active region which is configured to receive the electromagnetic radiation, wherein the active zone and the active region are of the same composition. The fact that the active region and the active zone can be of the same composition can be due to the fact that the emitter and the receiver are grown laterally adjacent to each other. Thereby it is possible that emitter and receiver are grown at the same time under the same growth conditions.

Thereby it is also possible that the active zone of the emitter and the active region of the receiver, which are grown laterally adjacent to each other, have a similar composition. For example, the composition of the active region of the emitter and/or the composition of the active zone of the receiver can be changed after growth by implanting of material or other techniques which e.g. lead to quantum well intermixing in the active zone or active region. As a result the active zone and the active region are, in this case, no longer of the same but of a similar composition.

Further, the active region and the active zone can be grown by “Selective Area Growth”. In this case the active zone and the active region are grown in different dielectric masked areas. With this technique different bandgaps and/or thicknesses of the active region and the active zone can be set.

According to at least one aspect of the optoelectronic device the device comprises a carrier, wherein the emitter and the receiver are arranged laterally spaced apart on the carrier. As explained above the carrier can be formed at least in part by a growth substrate for the emitter and the receiver. However, it is also possible that the carrier is a different element, for example a circuit board like e.g. a printed circuit board. With such a carrier it is possible to electrically connect the emitter and the receiver and to operate them accordingly. For this purpose the carrier can also comprise switches and/or controllers for driving the emitter and the receiver.

The emitter and the receiver are arranged laterally spaced apart on the carrier, for example in such a way that the active zone and the active region are arranged in a common plane. Even if the emitter and the receiver are arranged laterally spaced apart from each other, it is possible that they are mechanically interconnected with each other not only by the carrier, but by further elements of the device.

According to at least one aspect of the optoelectronic device, the emitter is an edge-emitting semiconductor chip which is configured to emit the electromagnetic radiation in a lateral direction and the receiver is configured to receive the electromagnetic radiation from the lateral direction. The lateral direction is in the same plane as the lateral direction explained above.

In the present context, an edge-emitting semiconductor chip is understood to be a radiation-emitting component which emits the electromagnetic radiation generated during operation transversely, in particular perpendicularly, to a side surface or facet of the chip. The electromagnetic radiation is then emitted, for example, through the side surface or facet. In particular, the edge-emitting semiconductor chip may be a semiconductor device comprising an epitaxially grown semiconductor body. In particular, the direction in which the electromagnetic radiation is then emitted during operation may be oblique or perpendicular to a growth direction of the semiconductor body. For example, the semiconductor body may be based on semiconductor materials such as In(Ga)N, In(Ga)AlP, (Al)GaAs, (In)GaAs.

The edge-emitting semiconductor chip may be, for example, a light-emitting diode or a laser diode, in particular a superluminescent diode or an edge-emitting semiconductor laser.

Thereby it is also possible that the emitter emits the electromagnetic radiation from two sides, for example through two facets or side surfaces which are arranged opposite each other in the edge-emitting semiconductor chip.

According to at least one aspect of the optoelectronic device, the active zone of the emitter and the active region of the receiver are adjacent to each other and the active zone of the emitter and the active region of the receiver are interconnected.

In this case the emitter and the receiver, which are grown laterally adjacent to each other, are not completely separated from each other during and after growth but they remain interconnected at least at their respective active zone or region. In this way it is possible that the electromagnetic radiation can be guided from the active zone to the active region by the element interconnecting them. In this way the active zone and the active region form a waveguide for the electromagnetic radiation. With this it is possible, for example, that the electromagnetic radiation can be coupled very efficiently from the emitter into the receiver. Thereby it is also possible that more than one receiver is optically coupled by the active zone and active region to the same emitter.

In the case that the connection between the emitter and the receiver is due to elements of the emitter and the receiver which are not removed during or after growth, the active region and the active zone can be monolithically integrated with each other. That is to say, they are grown together in the same growth process and not interconnected with each other after their fabrication but during their fabrication.

According to at least one aspect of the optoelectronic device, the emitter is a surface-emitting semiconductor chip which is configured to emit the electromagnetic radiation in a vertical direction and the receiver is configured to receive the electromagnetic radiation from the vertical direction.

In the present context, a surface-emitting semiconductor chip is understood to mean a radiation-emitting component which emits the electromagnetic radiation generated during operation transversely, in particular perpendicularly, to a mounting surface on which the radiation-emitting component is mounted. In particular, the surface-emitting semiconductor chip may be a semiconductor device comprising an epitaxially grown semiconductor body. In particular, the direction in which the electromagnetic radiation is then emitted during operation may be parallel to a growth direction of the semiconductor body. For example, the semiconductor body may be based on semiconductor materials such as In (Ga) N, In(Ga)AlP, (Al)GaAs, (In)GaAs.

The surface-emitting semiconductor chip may be, for example, a light-emitting diode or a laser diode, in particular a superluminescent diode or a VCSEL.

According to at least one aspect of the optoelectronic device, an optical system is present which directs or guides the electromagnetic radiation from the emitter to the receiver. The optical system, for example, comprises one or more optical elements like reflecting and/or diffusing and/or diffracting optical devices. The optical system is arranged downstream of the emitter in the vertical direction. For example, the electromagnetic radiation emitted from the emitter is guided along a top surface of the emitter and into a top surface of the receiver, where it is absorbed.

According to at least one aspect of the optoelectronic device, the optical system is integrated into a potting body for the emitter and the receiver or the optical system is part of the potting body. According to this aspect, the emitter and the receiver are, for example at surfaces not covered by the carrier, covered by a potting body which is formed with an electrically insulating material. This electrically insulating material is transparent for the electromagnetic radiation. For example, the potting body comprises a silicone material, an epoxy material or a glass material, for example a spin-on glass. The potting material forms a mechanical and chemical protection for the emitter and the receiver against external influences. For example, the optical system comprises optical elements which are formed by mirrored outer surfaces of the potting body or outer surfaces of the potting body are configured for total internal reflection of electromagnetic radiation.

According to at least one aspect of the optoelectronic device, the device comprises a plurality of receivers which are connected in series with each other and/or a plurality of emitters which are connected in parallel with each other. That is to say, a plurality of receivers, for example of the same composition and/or a plurality of emitters, for example of the same composition, are grown laterally adjacent to each other and, for example, arranged on a common carrier. Thereby it is, for example, possible that one emitter is assigned to a plurality of receivers, wherein “is assigned” means that the electromagnetic radiation produced by this emitter is coupled into and absorbed by the assigned receivers.

With such a device it is possible, for example, that the input voltage of the device is lower than the output voltage.

The optical device can then be used to transform a lower voltage into a higher voltage.

According to at least one aspect of the optoelectronic device, the device further comprises a bypass diode for the receiver, wherein the bypass diode is connected in antiparallel to the receiver. Such a bypass diode can, for example, be used to shunt a receiver which is not illuminated. In this way a receiver which is not working or which is not operated is not destroyed by becoming reverse biased, but the current can flow through the bypass diode which is connected in antiparallel.

According to at least one aspect of the optoelectronic device, the bypass diode and the receiver are physically connected to each other. Thereby it is possible, for example, that the bypass diode and the receiver are monolithically integrated with each other or bonded to each other. Here, monolithically integrated means that the bypass diode can be grown epitaxially onto the receiver. Further, it is possible that the bypass diode and the receiver are grown laterally adjacent to each other. In this way both elements are arranged for example side by side in a lateral direction. In this case, the bypass diode and the receiver are semiconductor devices which are epitaxially grown along a growth direction onto a common growth substrate which acts as a carrier for the emitter and the receiver.

In the following the optoelectronic device described herein is explained in more detail by means of exemplary embodiments and the associated figures.

### BRIEF DESCRIPTION OF THE DRAWINGS

FIGS. 1A, 1B, and 1C schematically show an optoelectronic device according to the present disclosure.

FIG. 2 schematically shows an optoelectronic device according to the present disclosure.

FIG. 3 schematically shows an optoelectronic device according to the present disclosure.

FIG. 4 schematically shows an optoelectronic device according to the present disclosure.

FIGS. 5A and 5B schematically show an optoelectronic device according to the present disclosure.

FIGS. 6A and 6B schematically show an optoelectronic device according to the present disclosure.

### DETAILED DESCRIPTION

In the exemplary embodiments and figures, similar or similarly acting constituent parts are provided with the same reference symbols. The elements illustrated in the figures and their size relationships among one another should not be regarded as true to scale. Rather, individual elements may be represented with an exaggerated size for the sake of better representability and/or for the sake of better understanding.

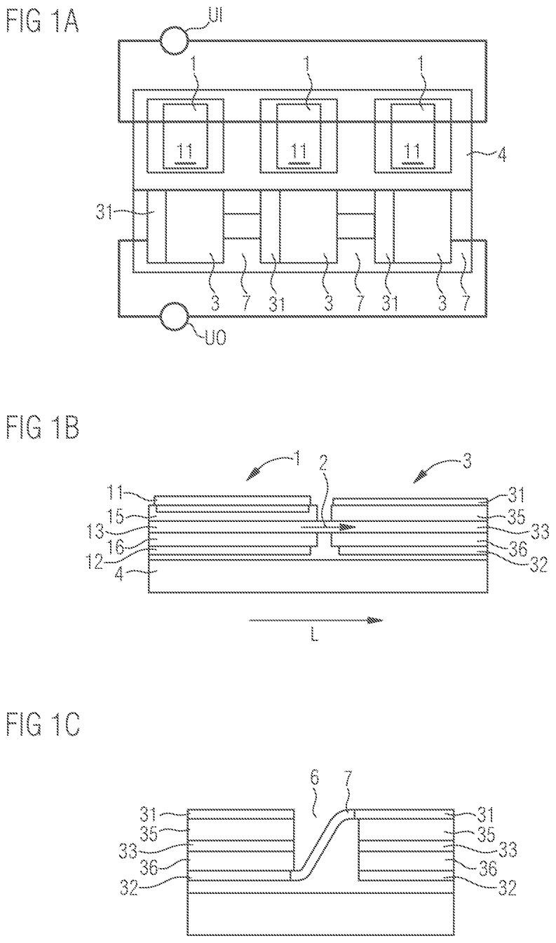

FIG. 1A shows a schematic top view of an embodiment of a here described device. FIGS. 1B and 1C show respective sectional views.

In the embodiment of FIGS. 1A to 1C, the optoelectronic device comprises an emitter 1 which is arranged to emit electromagnetic radiation 2 and configured to be operated with an input voltage UI. For this the device, for example, comprises three emitters 1 which are connected in parallel with each other.

The optoelectronic device further comprises receivers 3 which are arranged to receive the electromagnetic radiation 2 and configured to provide at least part of an output voltage. For this the device, for example, comprises three receivers 3 which are connected in series with each other.

Each emitter 1, for example, comprises a first contact 11 for electrically connecting the emitter, a second contact 12, and an active zone 13 in which the electromagnetic radiation 2 is produced. The emitter further comprises a first doped zone 15 and a second doped zone 16, between which the active zone is arranged. The emitter 1 of the embodiment of FIGS. 1A to 1C is, for example, an edge-emitting laser chip.

The receiver 3 arranged adjacent and laterally spaced apart from the emitter 1 comprises, for example, a first contact 31, a second contact 32, and an active region 33 for absorbing the electromagnetic radiation 2 which is arranged between a first doped region 35 and a second doped region 36.

Emitters 1 and receivers 3 are arranged on a carrier 4 which can be, for example, a circuit board by which the components of the optoelectronic device can be electrically contacted and controlled.

The emitters 1 and receivers 3 can, for example, be surrounded at least partly by an electrically insulating potting body 6, which forms a chemical and mechanical protection of the emitters 1 and receivers 3. In this embodiment emitters 1 and receivers 3, assigned to each other, are adjacent to each other and the active zone 13 of the emitter 1 and the active region 33 of the receiver 3 are interconnected. For this, for example, the doped regions and zones are at least partially removed between the emitter 1 and the receiver 3.

As becomes clear, for example from FIG. 1C, the receivers are connected in series by an electrical connection 7 which connects the second contact 32 of the receiver 3 with the first contact 31 of a neighbouring receiver 3. The electrical connection 7 can be embedded in the potting body 6 and be electrically and chemically protected by this potting body from external influences.

In the embodiment of FIGS. 1A to 1C, the emitter 1 and the assigned receiver 3 are connected by their active zone and region. However, it is also possible to etch grooves through the whole material between the emitter 1 and the receiver 3 and thus separate the two devices from each other. In each case the at least partial separation between emitter 1 and receiver 3 reduces the effect of a highinput voltage at the receiver 3 on the emitters. For example, the emitters 1 can be distributed feedback lasers or distributed Bragg reflector lasers for adjusting the emission wavelength of the electromagnetic radiation 2 to achieve an optimum absorption in the receivers 3.

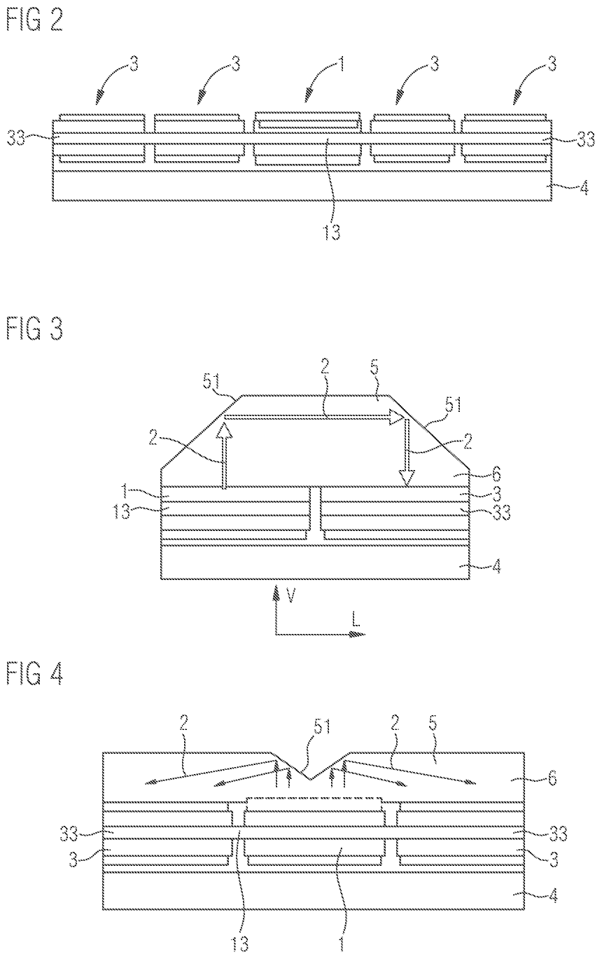

The schematic sectional view of FIG. 2 shows an embodiment of a here described optoelectronic device where, in comparison to the embodiment of FIGS. 1A to 1C, an additional row of receivers is arranged behind a first row of receivers and further rows of receivers 3 are arranged at a side of the emitter 1 facing away from the first row of receivers 3. In this case, each emitter for example couples its radiation into four receivers which can all be connected in series with each other. With such an arrangement a higher output voltage can be reached. Further, it is feasible to add further receivers for each emitter in the same way.

In all embodiments, both emitter 1 and receiver 3 can be multi-junction and optionally multi-wavelength devices, which allows for higher voltages and/or higher currents.

FIG. 3 shows a schematic sectional view of a device described here. The device comprises an emitter 1, which comprises a surface-emitting semiconductor chip. Furthermore, the device comprises a receiver 3, which comprises at least a photodiode. Emitter 1 and receiver 3 are arranged on the top surface of a carrier 4.

The emitter 1 comprises a radiation exit surface directed away from the top surface of the carrier 4. The receiver 3 comprises a radiation entrance face directed away from the carrier 4.

The emitter 1 and receiver 3 are surrounded by a common potting body 6. The potting body 6 is formed with a transparent material that is transparent to the wavelength of the electromagnetic radiation 2 generated in the emitter 1. For example, the electromagnetic radiation 2 is in a wavelength range of at least 350 to at most 1600 nm. For example, the potting body 6 may be formed with an epoxy-based material or a silicone-based material or a glass-based material. The potting body 6 is formed on the emitter 1 and the receiver 3, and covers surfaces of these components that are not covered by the carrier 4.

The potting body 6 forms an optical system 5 for directing, guiding and/or focusing the electromagnetic radiation 2.

In the embodiment of FIG. 3, the optical system 5 comprises optical elements 51 formed as reflective surfaces. The electromagnetic radiation 2 emitted by the emitter 1 is first reflected by an optical element 51 so that it is parallel to the main extension plane or cover surface of the carrier 4. After further reflection at another optical element 51, the electromagnetic radiation 2 runs perpendicular to the main extension plane or cover surface of the carrier 4 and impinges on the receiver 3 at its radiation entrance side.

An input voltage UI is applied to the emitter 1. An output voltage UO is obtained from the receiver 3. The input voltage and the output voltage may be the same or different. The optoelectronic device may thus be set up to transmit energy and/or convert voltage.

The redirection of the electromagnetic radiation 2 at the optical elements 51 may be performed, for example, by total internal reflection, or the outer surface of the potting body 6 may be coated with a reflective material arranged to reflect the electromagnetic radiation 2, for example from the infrared range. For example, the optical element 51 may comprise a coating of gold or silver.

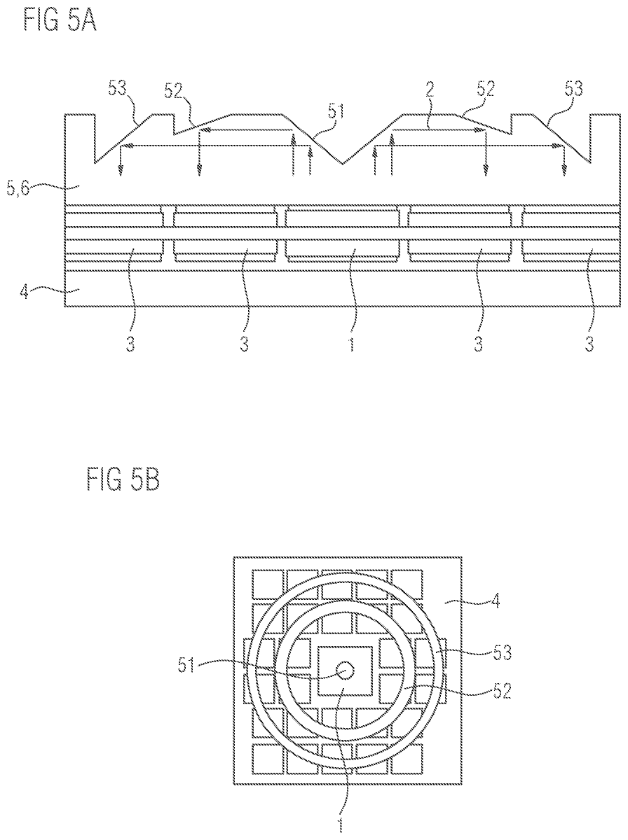

In connection with the schematic sectional view of FIG. 4, a further embodiment of a device described here is explained in more detail.

In the embodiment of FIG. 4, the device comprises a plurality of receivers 3 arranged on the top surface of the carrier 4, for example, point-symmetrically around the emitter 1, which comprises, for example, a single surface-emitting semiconductor chip. The emitter 1 and the receiver 3 are surrounded by a potting body 6 which forms an optical system 5 having an optical element 51 which is radiation reflective. The optical element 51 redirects the electromagnetic radiation 2 generated in the emitter 1 to the radiation entrance sides of the receivers 3. In this case, the optical element 51 is formed, for example, as a conical recess in the potting body 6, the lateral surface of the cone being reflective.

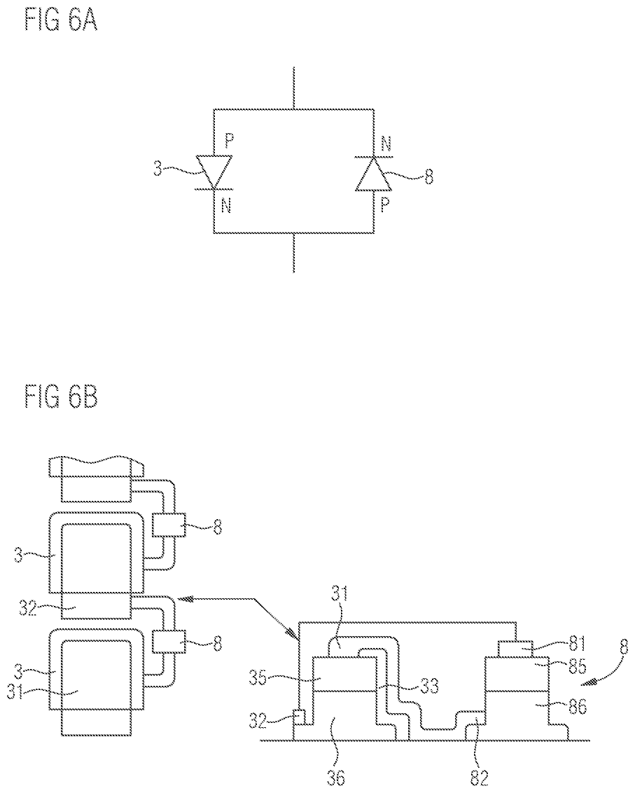

In connection with the schematic views of FIG. 6A and FIG. 6B, a further embodiment of a here described optoelectronic device is discussed. Here, a bypass diode 8 is assigned to each receiver 3 of the device. The bypass diode 8 can, for example, be monolithically integrated with the receiver 3 or it is bonded to the receiver 3. The bypass diode 8 comprises a pn-junction formed by first doped region 85 and second doped region 86 which is connected antiparallel to the pn-junction of the receiver 3, see FIG. 6B. The bypass diode 8 can shunt the receiver 3 in case the receiver 3 is not illuminated by the emitter 1 or the receiver 3 is defect. For example, in this way the receiver 3 is not destroyed by becoming reverse biased.

A connection between the bypass diode 8 and the receiver 3 can be, for example, established by contacts 31 and 32 of the receiver 3 as shown in FIG. 6B.

For the herein described optoelectronic device it is further possible that all emitters 1 are configured to be operable independently from each other. That is to say, for example all emitters 1 can be switched independently from each other so that each emitter 1 can be operated or not. In this way it is possible, for example, to switch off defect emitters or to control the output voltage of the optoelectronic device.

Further, all receivers 3 can be configured to be operable independently from each other. That is to say, each receiver 3 can be switched independently to be operated or not to be operated. Thereby it is possible, for example, to switch pairs of emitters 1 and receivers 3 on and off and thus to control the input voltage UI and the output voltage UO.

The invention is not restricted to the exemplary embodiments by the description on the basis of said exemplary embodiments. Rather, the invention encompasses any new feature and also any combination of features, which in particular comprises any combination of features in the patent claims and any combination of features in the exemplary embodiments, even if this feature or this combination itself is not explicitly specified in the patent claims or exemplary embodiments.

1. An optoelectronic device comprising
an emitter configured to emit electromagnetic radiation and configured to be operated with an input voltage,
a receiver configured to receive the electromagnetic radiation and configured to provide at least part of an output voltage, wherein
the emitter and the receiver are grown laterally adjacent to each other,
an active zone of the emitter and an active region of the receiver are adjacent to each other and the active zone of the emitter and the active region of the receiver are interconnected and the active zone and the active region form a waveguide for the electromagnetic radiation, and/or
an optical system directs or guides the electromagnetic radiation from the emitter to the receiver.

2. The optoelectronic device according to claim 1, wherein the emitter and the receiver are grown simultaneously.

3. The optoelectronic device according to claim 1, wherein the emitter comprises an active zone which is configured to produce the electromagnetic radiation and the receiver comprises an active region which is configured to receive the electromagnetic radiation, wherein the active zone and the active region are of the same composition.

4. The optoelectronic device according to claim 1, further comprising a carrier, wherein the emitter and the receiver are arranged laterally spaced apart on the carrier.

5. The optoelectronic device according to claim 1, wherein the emitter is an edge-emitting semiconductor chip which is configured to emit the electromagnetic radiation in a lateral direction and the receiver is configured to receive the electromagnetic radiation from the lateral direction.

6. The optoelectronic device according to claim 5, wherein the active zone and the active region are monolithically integrated with each other.

7. The optoelectronic device according to claim 1, wherein the emitter is a surface-emitting semiconductor chip which is configured to emit the electromagnetic radiation in a vertical direction and the receiver is configured to receive the electromagnetic radiation from the vertical direction.

8. The optoelectronic device according to claim 7, wherein the optical system is integrated into a potting body for the emitter and the receiver or the optical system is part of the potting body.

9. The optoelectronic device according to claim 1, further comprising a bypass diode for the receiver, wherein the bypass diode is connected in antiparallel to the receiver.

10. The optoelectronic device according to claim 9, wherein the bypass diode and the receiver are physically connected to each other.

11. The optoelectronic device according to claim 10, wherein the bypass diode and the receiver are monolithically integrated with each other or bonded to each other.

12. The optoelectronic device according to claim 1, having a plurality of receivers which are connected in series with each other and/or a plurality of emitters which are connected in parallel with each other.

13. The optoelectronic device according to claim 1, wherein the input voltage is lower than the output voltage.
